(19) United States
(12) Patent Application Publication
(10) Pub. No.: US 2015/0140704 A1
(43) Pub. Date: May 21, 2015

(54) CLEANING SOLUTION AND METHOD FOR MANUFACTURING DISPLAY DEVICE USING THE SAME

(71) Applicant: SAMSUNG DISPLAY CO., LTD., Yongin-City (KR)

(72) Inventors: Jong-Hyun CHOUNG, Yongin-City (KR); In-Bae KIM, Yongin-City (KR); Hongsick PARK, Yongin-City (KR); Hyeonjeong SANG, Yongin-City (KR); Jaewoo JEONG, Yongin-City (KR); Byung uk KIM, Yongin-City (KR); Suk Il YOON, Yongin-City (KR); Se Hwan JUNG, Yongin-City (KR); Soon Beom HUH, Yongin-City (KR)

(21) Appl. No.: 14/301,840

(22) Filed: Jun. 11, 2014

(30) Foreign Application Priority Data
Nov. 18, 2013 (KR) 10-2013-0140136

(51) Int. Cl. H01L 21/02

(52) U.S. Cl. CPC H01L 21/02052
USPC 438/28; 510/269

(57) ABSTRACT

A cleaning solution and a method for manufacturing a display device, the cleaning solution including about 2 wt % to about 12 wt % of nitric acid; about 0.5 wt % to about 15 wt % of an organic acid; about 0.1 wt % to about 10 wt % of a salt compound; about 0.01 wt % to about 3 wt % of an inorganic salt that includes fluorine; and a balance of water, all amounts being based on a total weight of the cleaning solution.

### CROSS-REFERENCE TO RELATED APPLICATIONS

Korean Patent Application No. 10-2013-0140136, filed on Nov. 18, 2013, in the Korean Intellectual Property Office, and entitled: “Cleaning Solution and Method for Manufacturing Display Device using the Same,” is incorporated by reference herein in its entirety.

### BACKGROUND

1. Field

Embodiments relate to a cleaning solution and a method for manufacturing a display device using the same.

2. Description of the Related Art

A display panel is a switching device for driving pixels and may include a display substrate having thin film transistors formed thereon. The display substrate may include a plurality of metal patterns, and the metal patterns may be mostly formed by a photolithography process. According to the photolithography process, a photoresist layer may be formed on an etchable thin film on the substrate, the photoresist layer may be exposed and developed to form a photoresist pattern, and the thin film may be patterned through etching the thin film using an etchant and using the photoresist pattern as an etch stopping layer.

### SUMMARY

Embodiments are directed to a cleaning solution and a method for manufacturing a display device using the same.

The embodiments may be realized by providing a cleaning solution including about 2 wt % to about 12 wt % of nitric acid; about 0.5 wt % to about 15 wt % of an organic acid; about 0.1 wt % to about 10 wt % of a salt compound; about 0.01 wt % to about 3 wt % of an inorganic salt that includes fluorine; and a balance of water, all amounts being based on a total weight of the cleaning solution.

The nitric acid may be included in an amount of about 5 wt % to about 10 wt %.

The organic acid may be included in an amount of about 1 wt % to about 10 wt %.

The organic acid may include at least one selected from the group of succinic acid, ascorbic acid, formic acid, sulfonic acid, glycolic acid, acetic acid, oxalic acid, malic acid, uric acid, or citric acid.

The salt compound may be included in an amount of about 0.5 wt % to about 5 wt %.

The salt compound may include at least one selected from the group of potassium acetate, potassium nitrate, potassium carbonate, potassium pyrophosphate, potassium oleate, potassium benzoate, potassium laurate, potassium tert-butoxide, potassium sulfate, potassium sorbate, or ammonium acetate.

The inorganic salt that includes fluorine may be included in an amount of about 0.1 wt % to about 1.5 wt %.

The inorganic salt that includes fluorine may include at least one selected from the group of ammonium bifluoride, potassium fluoride, ammonium fluoride, hydrofluoric acid, or sodium fluoride.

The water may be deionized water.

The cleaning solution may further include a surfactant.

The embodiments may be realized by providing a method for manufacturing a display device, the method including cleaning a substrate using a cleaning solution; forming a thin film transistor on the substrate; and forming a pixel electrode on the thin film transistor, wherein the cleaning solution includes about 2 wt % to about 12 wt % of nitric acid; about 0.5 wt % to about 15 wt % of an organic acid; about 0.1 wt % to about 10 wt % of a salt compound; about 0.01 wt % to about 3 wt % of an inorganic salt that includes fluorine; and a balance of water, all amounts being based on a total weight of the cleaning solution.

The substrate may be a glass substrate formed by processing glass.

The method may further include rinsing the substrate after cleaning the substrate.

The method may further include drying the substrate after rinsing the substrate.

The cleaning solution may further include a surfactant.

The embodiments may be realized by providing a method for manufacturing a display device, the method including cleaning a substrate using a cleaning solution; forming a black matrix on the substrate; and forming a color layer on the substrate, wherein the cleaning solution includes about 2 wt % to about 12 wt % of nitric acid; about 0.5 wt % to about 15 wt % of an organic acid; about 0.1 wt % to about 10 wt % of a salt compound; about 0.01 wt % to about 3 wt % of an inorganic salt that includes fluorine; and a balance of water, all amounts being based on a total weight of the cleaning solution.

The substrate may be a glass substrate formed by processing glass.

The method may further include rinsing the substrate after cleaning the substrate.

The method may further include drying the substrate after rinsing the substrate.

The cleaning solution may further include a surfactant.

### BRIEF DESCRIPTION OF THE DRAWINGS

Features will be apparent to those of skill in the art by describing in detail exemplary embodiments with reference to the attached drawings in which:

FIG. 1 illustrates a flowchart of a method for manufacturing a display device according to the first embodiment;

FIGS. 2 to 6 illustrate cross-sectional views of stages in a method for manufacturing a display device according to the first embodiment in order;

FIG. 7 illustrates a flowchart of a method for manufacturing a display device according to the first embodiment;

FIGS. 8 to 10 illustrate cross-sectional views of stages in a method for manufacturing a display device according to the first embodiment in order;

FIG. 11 illustrates a cross-sectional view of a portion of a display device manufactured by the method for manufacturing a display device illustrated in FIGS. 2 to 6 and FIGS. 8 to 10;

FIGS. 12A to 12C illustrate images of the specimen of an organic material (FIG. 12A), the specimen of an inorganic material (FIG. 12B), and the specimen of an iron oxide sample (FIG. 12C);

FIGS. 13A to 13C illustrate images after cleaning using a cleaning solution of Example 1 for the specimen of an organic material (FIG. 13A), the specimen of an inorganic material (FIG. 13B), and the specimen of iron oxide (FIG. 13C); and

FIGS. 14A to 14C illustrate images after cleaning using a cleaning solution of Comparative Example 1 for the specimen of an organic material (FIG. 14A), the specimen of an inorganic material (FIG. 14B), and the specimen of an iron oxide (FIG. 14C).

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will also be understood that when a layer, a film, a region, a plate, etc. is referred to as being ‘on’ another layer, film, region, plate, etc., it can be directly on the other layer, film, region, plate, etc., or intervening elements may also be present.

Hereinafter a cleaning solution according to the first embodiment concept will be explained in detail.

The cleaning solution according to the first embodiment may include, e.g., about 2 wt % to about 12 wt % of nitric acid, about 0.5 wt % to about 15 wt % of an organic acid, about 0.1 wt % to about 10 wt % of a salt compound, about 0.01 wt % to about 3 wt % of an inorganic salt that includes fluorine, and a balance of water. For example, all amounts may be based on 100 wt % of the cleaning solution.

The nitric acid may remove, e.g, an organic material, an inorganic material, or the like, on a substrate. In an implementation, the nitric acid may be included in an amount of about 2 wt % to about 12 wt %, e.g., about 5 wt % to about 10 wt %. Maintaining the amount of the nitric acid at about 2 wt % or greater may help prevent deterioration of the cleaning power with respect to the organic material and the inorganic material, thereby facilitating complete removal of the organic material and the inorganic material. Maintaining the amount of the nitric acid at about 12 wt % or less may help ensure that the relative amounts of the organic acid, the salt compound, and the like are not decreased, and that a cleaning time is not prolonged.

In addition, the organic acid may penetrate into iron oxide or the like to remove the iron oxide, as well as organic materials remaining on the substrate. In an implementation, the organic acid may be included in an amount of about 0.5 wt % to about 15 wt %, e.g., about 1 wt % to about 10 wt %. Maintaining the amount of the organic acid at about 0.5 wt % or greater may facilitate the complete removal of iron oxide. Maintaining the amount of the organic acid at about 15 wt % or less may help ensure that the relative amounts of the nitric acid, the salt compound, and the like are not decreased, and that a cleaning time is not prolonged.

A suitable organic acid may be used, and may include, e.g., and at least one selected from the group of succinic acid, ascorbic acid, formic acid, sulfonic acid, glycolic acid, acetic acid, oxalic acid, malic acid, uric acid and citric acid.

In addition, the salt compound may help remove any of the organic material and the inorganic material remaining on the substrate. In an implementation, the salt compound may be included in an amount of about 0.1 wt % to about 10 wt %, e.g., about 0.5 wt % to about 5 wt %. Maintaining the amount of the salt compound at about 0.1 wt % or greater may help ensure that the organic material is sufficiently removed. Maintaining the amount of the salt compound at about 10 wt % or less may help prevent waste and improve economy because the removing or cleaning power of the organic material may not be increased any further.

A suitable salt compound may be used and may include, e.g., at least one selected from the group of potassium acetate, potassium nitrate, potassium carbonate, potassium pyrophosphate, potassium oleate, potassium benzoate, potassium laurate, potassium tert-butoxide, potassium sulfate, potassium sorbate, and ammonium acetate.

In addition, the inorganic salt that includes fluorine may help remove any of the organic material, the inorganic material, the iron oxide, or the like remaining on the substrate. In an implementation, the inorganic salt that includes fluorine may be included in an amount of about 0.01 wt % to about 3 wt %, e.g., about 0.1 wt % to about 1.5 wt %. Maintaining the amount of the inorganic salt that includes fluorine at about 0.01 wt % or greater may help ensure that the organic material, the inorganic material, and the iron oxide are sufficiently removed. Maintaining the amount of the inorganic salt that includes fluorine at about 3 wt % or less may help prevent waste and improve economy because the removing or cleaning power of the organic material, the inorganic material, and the iron oxide may not be increased any further. In addition, maintaining the amount of the inorganic salt that includes fluorine at about 3 wt % or less may help ensure that the amount of the fluorine is small, which may be desirable when considering environmental aspect.

A suitable inorganic salt that includes fluorine may be used and may include, e.g., at least one selected from the group of ammonium bifluoride, potassium fluoride, ammonium fluoride, hydrofluoric acid, and sodium fluoride. In an implementation, the inorganic salt that includes fluorine may be different from the salt compound.

The water may include, e.g., deionized water. In an implementation, the water may be pure water filtered through an ion exchange resin and/or may be ultra-pure water having specific resistance of greater than or equal to about 18 MΩ. The amount of the water may be the balance amount and the total amount of the cleaning solution is 100 wt %.

A method for manufacturing a display device according to the first embodiment will be explained.

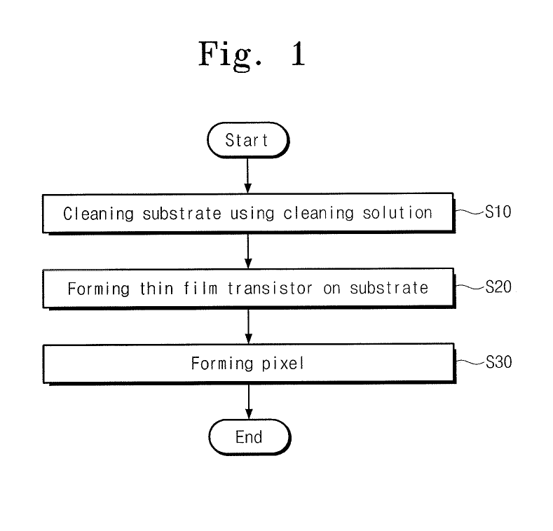

FIG. 1 illustrates a flowchart of a method for manufacturing a display device according to the first embodiment.

The method for manufacturing a display device according to the first embodiment may include, e.g., a step of cleaning a substrate using a cleaning solution (S10), a step of forming a thin film transistor on the substrate (S20), and a step of forming a pixel electrode on the thin film transistor (S30).

The cleaning solution may be the same cleaning solution described above. For example, the cleaning solution may include about 2 wt % to about 12 wt % of nitric acid, about 0.5 wt % to about 15 wt % of an organic acid, about 0.1 wt % to about 10 wt % of a salt compound, about 0.01 wt % to about 3 wt % of an inorganic salt that includes fluorine, and a balance amount of water, all amounts being based on the total weight of the cleaning solution.

First, a substrate may be prepared, and the substrate may be transferred into a chamber for performing processes.

A suitable substrate may be used. For example, the substrate may be a flexible substrate and may include a plastic having good heat resistance and durability such as polyethylene terephthalate, polyethylene naphthalate, polycarbonate, polyarylate, polyetherimide, polyethersulfone, or polyimide. In an implementation, the substrate may be formed by using various materials such as a metal or glass. Referring to FIG. 1, the substrate may be cleaned using the cleaning solution (S10). As noted above, the cleaning solution may include about 2 wt % to about 12 wt % of nitric acid, about 0.5 wt % to about 15 wt % of an organic acid, about 0.1 wt % to about 10 wt % of a salt compound, about 0.01 wt % to about 3 wt % of an inorganic salt that includes fluorine, and a balance amount of water, all amounts being based on the total weight of the cleaning solution. By cleaning the substrate using the cleaning solution, any of the organic material, the inorganic material, the iron oxide, or the like remaining on the substrate may be removed.

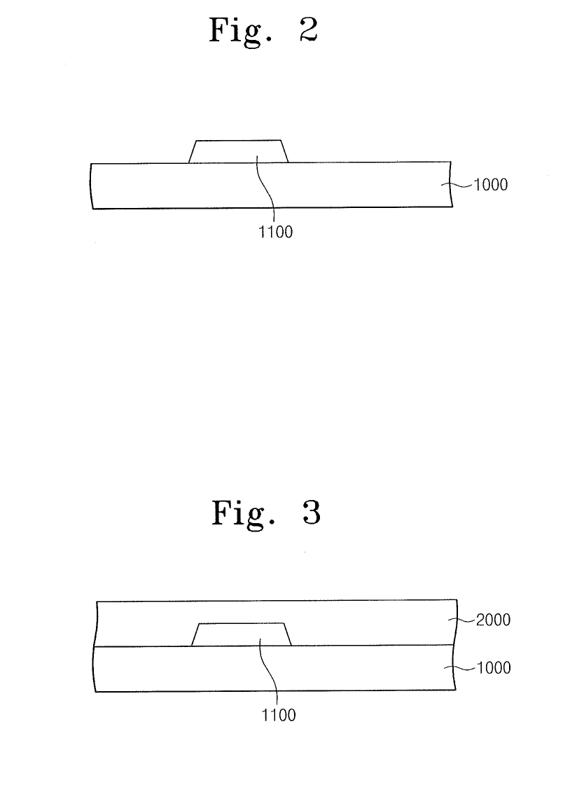

Then, referring to FIG. 1, a thin film transistor TFT may be formed on the cleaned substrate (S20). The thin film transistor TFT may include a gate electrode 1100, a gate insulating layer 2000, a semiconductor pattern 2100, a source electrode 2300, and a drain electrode 2500 (see FIGS. 2-6). The thin film transistor TFT may be formed by patterning using a photolithography process.

FIGS. 2 to 6 illustrate cross-sectional views of stages in a method for manufacturing a display device according to the first embodiment in order.

Referring to FIG. 2, the gate electrode 1100 may be formed on the cleaned substrate 1000. Referring to FIG. 3, the gate insulating layer 2000 may be formed on the substrate 1000 on which the gate electrode 1100 is formed. The gate insulating layer 2000 may be disposed on the gate electrode 1100 and may cover the gate electrode 1100.

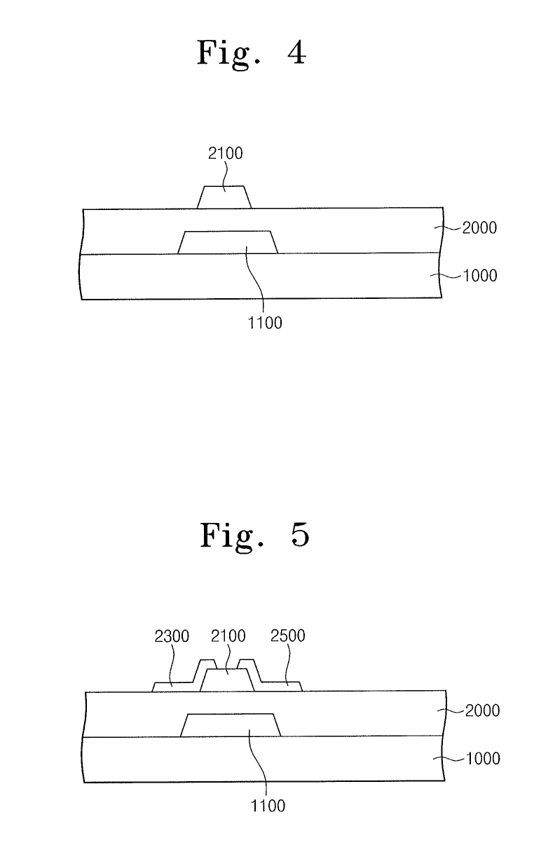

Then, referring to FIG. 4, the semiconductor pattern 2100 may be formed on the gate insulating layer 2000. The semiconductor pattern 2100 may face the gate electrode 1100 with the gate insulating layer 2000 therebetween.

Then, referring to FIG. 5, the source electrode 2300 and the drain electrode 2500 may be formed on the semiconductor pattern 2100. The source electrode 2300 and the drain electrode 2500 may be spaced apart from each other and may be connected to the semiconductor pattern 2100.

A first insulating layer 3000 may be further formed on the source electrode 2300 and the drain electrode 2500.

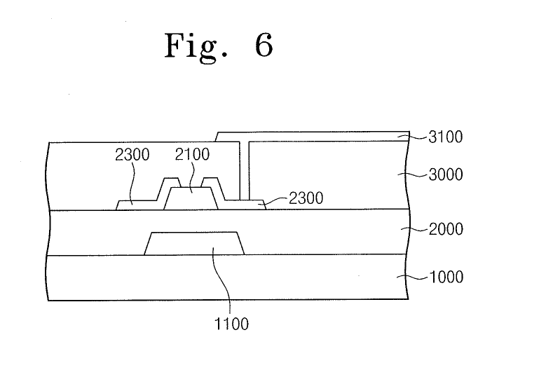

Then, referring to FIG. 6, a pixel electrode 3100 may be formed so as to be connected to the thin film transistor that includes the gate electrode 1100, the gate insulating layer 2000, the semiconductor pattern 2100, the source electrode 2300, and the drain electrode 2500 (S30). The pixel electrode 3100 may be disposed on the first insulating layer 3000.

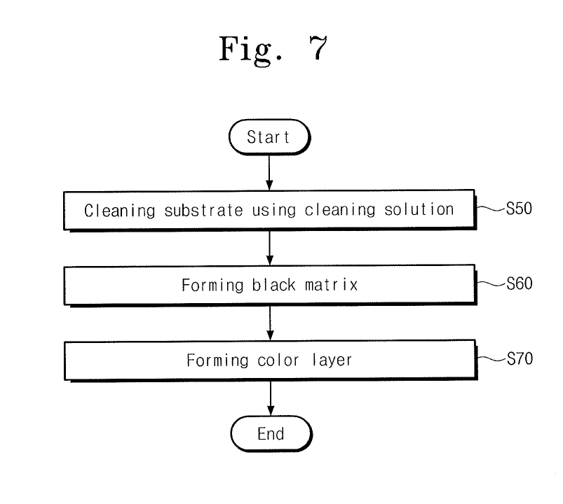

FIG. 7 illustrates a flowchart of a method for manufacturing a display device according to the first embodiment.

The method for manufacturing a display device according to the first embodiment may include, e.g., a step of cleaning a substrate using a cleaning solution (S50), a step of forming a black matrix on the substrate (S60), and a step of forming a color layer on the substrate (S70).

The cleaning solution may be the same cleaning solution described above. For example, the cleaning solution may include about 2 wt % to about 12 wt % of nitric acid, about 0.5 wt % to about 15 wt % of an organic acid, about 0.1 wt % to about 10 wt % of a salt compound, about 0.01 wt % to about 3 wt % of an inorganic salt that includes fluorine, and a balance amount of water, all amounts being based on the total weight of the cleaning solution.

First, a substrate may be prepared and transferred into a chamber for performing processes.

A suitable substrate may be used. In an implementation, the substrate may be a flexible substrate and may include a plastic having good heat resistance and durability such as polyethylene terephthalate, polyethylene naphthalate, polycarbonate, polyarylate, polyetherimide, polyethersulfone, or polyimide. In an implementation, the substrate may be formed by using various materials such as a metal or glass.

Referring to FIG. 7, the substrate may be cleaned using the cleaning solution (S50). The cleaning solution may include about 2 wt % to about 12 wt % of nitric acid, about 0.5 wt % to about 15 wt % of an organic acid, about 0.1 wt % to about 10 wt % of a salt compound, about 0.01 wt % to about 3 wt % of an inorganic salt that includes fluorine, and a balance amount of water, all amounts being based on the total weight of the cleaning solution. By cleaning the substrate using the cleaning solution, any of the organic material, the inorganic material, the iron oxide, or the like remaining on the substrate may be removed.

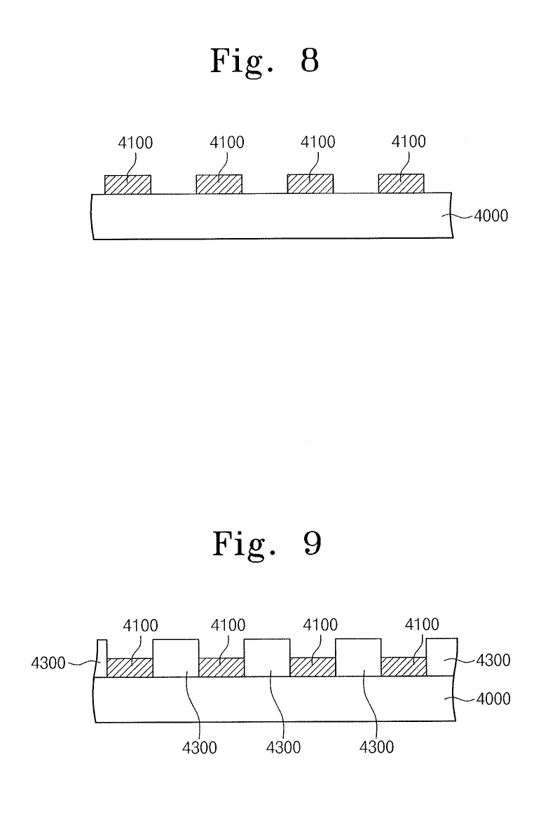

FIGS. 8 to 10 illustrate cross-sectional views of stages in a method for manufacturing a display device according to the first embodiment in order.

Referring to FIG. 8, first, a black matrix 4100 may be formed on the cleaned substrate 4000 (S60).

Then, referring to FIG. 9, a color layer 4300 may be formed on the substrate 4000 (S70). In an implementation, the forming order of the black matrix 4100 and the color layer 4300 may be such that the black matrix 4100 and the color layer 4300 are formed at the same time. In an implementation, the color layer 4300 may be formed first, e.g., prior to forming the black matrix 4100. The color layer 4300 may be a suitable color layer and may include, e.g., an RGB color layer.

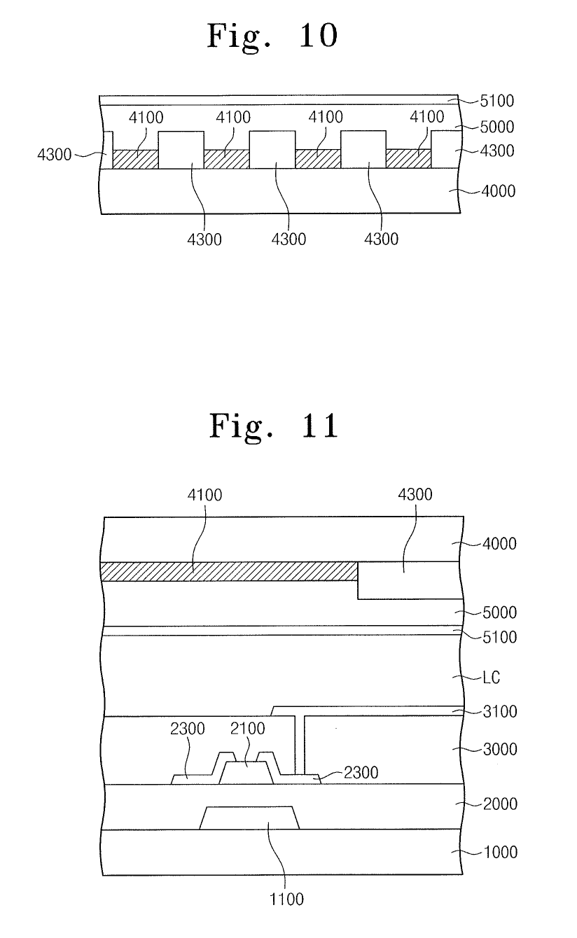

Then, referring to FIG. 10, a second insulating layer 5000 may be formed on the black matrix 4100 and the color layer 4300. In addition, a common electrode 5100 may be formed on the second insulating layer 5000.

In FIG. 10, the common electrode 5100 is illustrated as being formed on the substrate 4000 on which a color filter has been formed. In an implementation, the common electrode 5100 may be formed on the substrate 1000 on which the thin film transistor is formed while being insulated from the pixel electrode 3100.

FIG. 11 illustrates a cross-sectional view of a portion of a display device manufactured by the method for manufacturing a display device illustrated in FIGS. 2 to 6 and FIGS. 8 to 10. Referring to FIG. 11, a liquid crystal layer LC may be formed between the substrate 1000 on which the thin film transistor is formed and the substrate 4000 on which the color filter is formed.

When a display device is manufactured by the method for manufacturing a display device according to the first embodiment, any foreign materials on the substrate may be effectively removed by using the cleaning solution according to the first embodiment. The components of the cleaning solution may be the same as those of the cleaning solution according to the first embodiment as described above, and thus, a repeated detailed description thereon may be omitted. In an implementation, the cleaning solution may additionally include a surfactant.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Examples 1 to 5

Nitric acid, acetic acid (as an organic acid), ammonium acetate (as a salt compound), ammonium fluoride (as an inorganic salt that includes fluorine), and pure water were mixed according to the wt % listed in Table 1, below, to prepare cleaning solutions.

### Comparative Examples 1 to 6

Tetramethylammonium hydroxide (TMAH), potassium hydroxide (KOH), monoethanolamine (MEA) and pure water were mixed according to the wt % listed in Table 1 to prepare cleaning solutions.

TABLE 1

| | Nitric | Acetic | Ammonium | Ammonium | | | | Pure |
|---|---|---|---|---|---|---|---|---|
| | acid | acid | acetate | fluoride | TMAH | KOH | MEA | water |
| Example 1 | 7.5 | 4.0 | 1.0 | 0.4 | | | | 87.1 |
| Example 2 | 8.5 | 5.0 | 1.0 | 0.3 | | | | 85.2 |
| Example 3 | 9.5 | 5.5 | 0.8 | 0.3 | | | | 83.9 |
| Example 4 | 8.5 | 4.5 | 1.2 | 0.2 | | | | 85.6 |
| Example 5 | 7.5 | 5.5 | 0.9 | 0.3 | | | | 85.8 |
| Comparative | | | | | 0.4 | | | 99.6 |
| Example 1 | | | | | | | | |
| Comparative | | | | | | | 1 | 99 |
| Example 2 | | | | | | | | |
| Comparative | | | | | 1 | 0.5 | | 98.5 |
| Example 3 | | | | | | | | |
| Comparative | | | | | | 2.8 | | 97.2 |
| Example 4 | | | | | | | | |
| Comparative | | | | | 0.4 | 0.5 | 0.5 | 98.6 |
| Example 5 | | | | | | | | |
| Comparative | | | | | | | | 100 |
| Example 6 | | | | | | | | |

### Experimental Example 1

Cleaning performance of the cleaning solutions of Examples 1 to 5 and Comparative Examples 1 to 6 with respect to an organic material, an inorganic material, and iron oxide was evaluated.

### Manufacture of Specimens

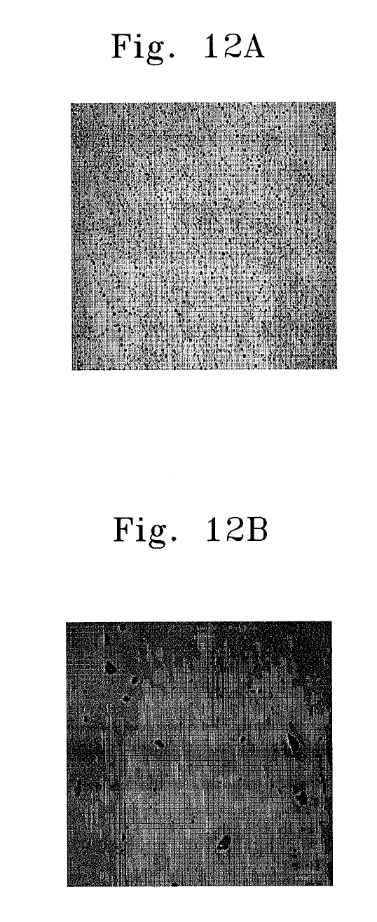

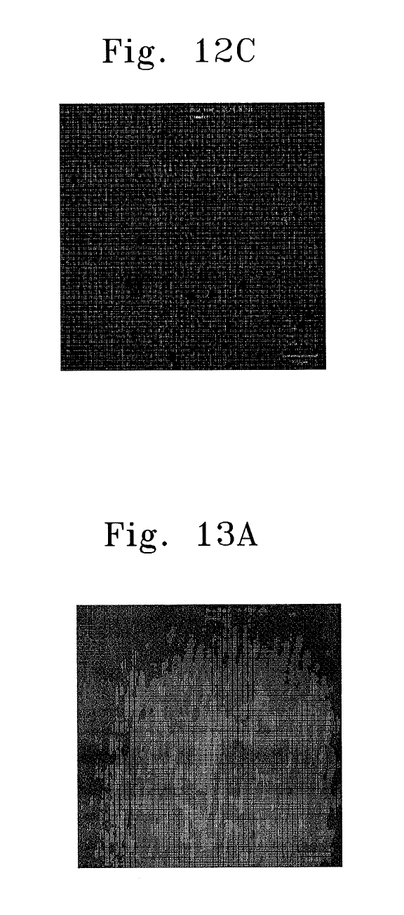

1. Manufacture of an organic specimen: Erucamide (TCI D1008) was cut into small pieces and dissolved in isopropyl alcohol to prepare a solution of about 0.2% (in percent concentration). A 7.5 cm×7.5 cm glass substrate was coated with the solution using a sprayer. Then, a drying process was performed in an oven at about 200° C. for about 5 minutes to prepare a specimen. An image of the specimen thus obtained is illustrated in FIG. 12A.

2. Manufacture of an inorganic specimen: A glass powder was put into acetone to prepare a solution of about 0.2% (in percent concentration). A 7.5 cm×7.5 cm glass substrate was coated with the solution using a sprayer. Then, a drying process was performed in an oven at about 200° C. for about 5 minutes to prepare a specimen. An image of the specimen thus obtained is illustrated in FIG. 12B.

3. Manufacture of an iron oxide specimen: Iron oxide (Fe₂O₃, KANTO CHEMICAL CO., INC) was put into pure water to prepare a solution of about 0.2% (in percent concentration). A 7.5 cm×7.5 cm glass substrate was coated with the solution using a sprayer. Then, a drying process was performed in an oven at about 200° C. for about 7 minutes to prepare a specimen. An image of the specimen thus obtained is illustrated in FIG. 12C.

### Measurement of Cleaning Power

1. Measuring Test of Cleaning Power

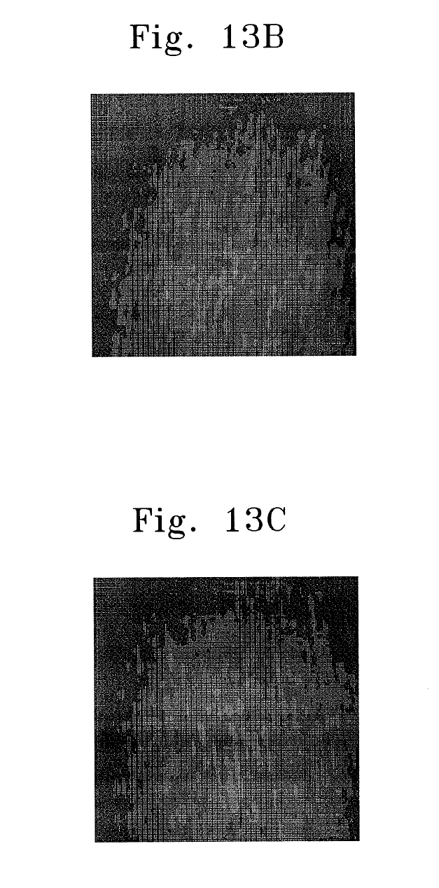

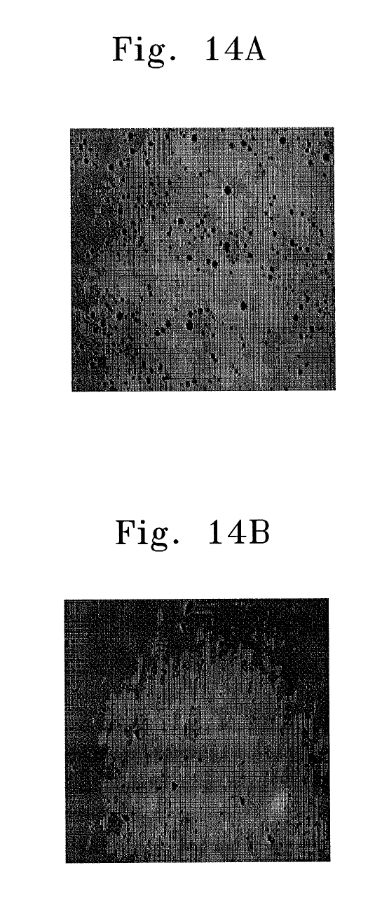

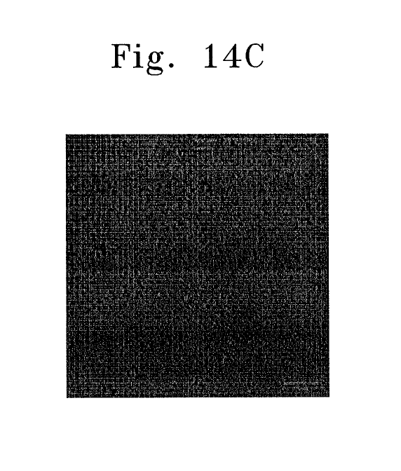

10 kg of the prepared cleaning solutions were put into a spraying apparatus, and the cleaning solutions were sprayed onto the organic specimen, the inorganic specimen, and the iron oxide specimen thus manufactured at 1 kg/cm² and about 30° C. for about 1 minute. Then, the specimens were cleaned using pure water for about 30 seconds and dried using nitrogen. The measured results are illustrated in Table 2, below. The analysis of the cleaning power was performed by measuring the cleaning degree using an optical microscope. The organic specimen, the inorganic specimen, and the iron oxide specimen were cleaned by using the cleaning solutions of Example 1 and Comparative Example 1, and the results are illustrated in FIGS. 13A, 13B, and 13C and 14A, 14B, and 14C, respectively.

TABLE 2

| | Measured result of cleaning power | | |
|---|---|---|---|
| Cleaning | Organic material | Inorganic material | Iron oxide |
| solution | (Erucamide) | (glass powder) | (Fe₂O₃) |
| Example 1 | ◯ | ◯ | ◯ |
| Example 2 | ◯ | ◯ | ◯ |
| Example 3 | ◯ | ◯ | ◯ |
| Example 4 | ◯ | ◯ | ◯ |
| Example 5 | ◯ | ◯ | ◯ |
| Comparative | X | X | X |
| Example 1 | | | |
| Comparative | X | X | X |
| Example 2 | | | |
| Comparative | X | Δ | X |
| Example 3 | | | |
| Comparative | X | Δ | X |
| Example 4 | | | |
| Comparative | X | Δ | X |
| Example 5 | | | |
| Comparative | X | X | X |
| Example 6 | | | |

◯: Cleaned
Δ: Some cleaned or a little cleaned
X: little cleaned or no cleaned

Referring to the above Table 2, FIGS. 13A, 13B, 13C, 14A, 14B, and 14C, when the organic specimen, the inorganic specimen, and the iron oxide specimen were respectively cleaned using the cleaning solutions of Examples 1 to 5, it may be seen that the cleaning power was good. When the organic specimen, the inorganic specimen, and the iron oxide specimen were respectively cleaned using the cleaning solutions of Comparative Examples 1 to 6, it may be seen that the cleaning power was deteriorated, and organic material, inorganic material, and/or iron oxide were present on each of the specimens after performing the cleaning.

By way of summation and review, when a substrate used for the manufacture of the display substrate including thin film transistors formed thereon is exposed to air for a long time, a surface of the substrate may be oxidized, and an oxide coating layer may be formed. In addition, an organic material, an inorganic material, or the like may be adsorbed on the surface of the substrate during processing or transporting the substrate.

To utilize the substrate that has foreign materials (such as the oxide coating layer, the organic material, and the inorganic material) thereon as a display substrate having the thin film transistor, the foreign materials on the substrate may be removed. To remove the foreign materials, the surface of the substrate may be cleaned using an acid.

The embodiments may provide a cleaning solution for effectively cleaning foreign materials on a substrate.

The embodiments may provide a method for manufacturing a display device in which foreign materials on a substrate may be effectively removed.

By using the cleaning solution according to an embodiment, foreign materials on a substrate may be effectively cleaned.

By the method of manufacturing a display device according to an embodiment, a display device in which foreign materials on a substrate is effectively cleaned may be obtained.

The embodiments may provide a cleaning solution for cleaning foreign materials on a substrate.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A cleaning solution, comprising:
about 2 wt % to about 12 wt % of nitric acid;
about 0.5 wt % to about 15 wt % of an organic acid;
about 0.1 wt % to about 10 wt % of a salt compound;
about 0.01 wt % to about 3 wt % of an inorganic salt that includes fluorine; and
a balance of water, all amounts being based on a total weight of the cleaning solution.

2. The cleaning solution as claimed in claim 1, wherein the nitric acid is included in an amount of about 5 wt % to about 10 wt %.

3. The cleaning solution as claimed in claim 1, wherein the organic acid is included in an amount of about 1 wt % to about 10 wt %.

4. The cleaning solution as claimed in claim 1, wherein the organic acid includes at least one selected from the group of succinic acid, ascorbic acid, formic acid, sulfonic acid, glycolic acid, acetic acid, oxalic acid, malic acid, uric acid, or citric acid.

5. The cleaning solution as claimed in claim 1, wherein the salt compound is included in an amount of about 0.5 wt % to about 5 wt %.

6. The cleaning solution as claimed in claim 1, wherein the salt compound includes at least one selected from the group of potassium acetate, potassium nitrate, potassium carbonate, potassium pyrophosphate, potassium oleate, potassium benzoate, potassium laurate, potassium tert-butoxide, potassium sulfate, potassium sorbate, or ammonium acetate.

7. The cleaning solution as claimed in claim 1, wherein the inorganic salt that includes fluorine is included in an amount of about 0.1 wt % to about 1.5 wt %.

8. The cleaning solution as claimed in claim 1, wherein the inorganic salt that includes fluorine includes at least one selected from the group of ammonium bifluoride, potassium fluoride, ammonium fluoride, hydrofluoric acid, or sodium fluoride.

9. The cleaning solution as claimed in claim 1, wherein the water is deionized water.

10. The cleaning solution as claimed in claim 1, further comprising a surfactant.

11. A method for manufacturing a display device, the method comprising:
cleaning a substrate using a cleaning solution;
forming a thin film transistor on the substrate; and
forming a pixel electrode on the thin film transistor,
wherein the cleaning solution includes:
about 2 wt % to about 12 wt % of nitric acid;
about 0.5 wt % to about 15 wt % of an organic acid;
about 0.1 wt % to about 10 wt % of a salt compound;
about 0.01 wt % to about 3 wt % of an inorganic salt that includes fluorine; and
a balance of water, all amounts being based on a total weight of the cleaning solution.

12. The method for manufacturing a display device as claimed in claim 11, wherein the substrate is a glass substrate formed by processing glass.

13. The method for manufacturing a display device as claimed in claim 11, further comprising rinsing the substrate after cleaning the substrate.

14. The method for manufacturing a display device as claimed in claim 13, further comprising drying the substrate after rinsing the substrate.

15. The method for manufacturing a display device as claimed in claim 11, wherein the cleaning solution further includes a surfactant.

16. A method for manufacturing a display device, the method comprising:
cleaning a substrate using a cleaning solution;
forming a black matrix on the substrate; and
forming a color layer on the substrate,
wherein the cleaning solution includes:
about 2 wt % to about 12 wt % of nitric acid;
about 0.5 wt % to about 15 wt % of an organic acid;
about 0.1 wt % to about 10 wt % of a salt compound;
about 0.01 wt % to about 3 wt % of an inorganic salt that includes fluorine; and
a balance of water, all amounts being based on a total weight of the cleaning solution.

17. The method for manufacturing a display device as claimed in claim 16, wherein the substrate is a glass substrate formed by processing glass.

18. The method for manufacturing a display device as claimed in claim 16, further comprising rinsing the substrate after cleaning the substrate.

19. The method for manufacturing a display device as claimed in claim 18, further comprising drying the substrate after rinsing the substrate.

20. The method for manufacturing a display device as claimed in claim 16, wherein the cleaning solution further includes a surfactant.
